(19) United States
(12) Patent Application Publication
(10) Pub. No.: US 2003/0214847 A1
(43) Pub. Date: Nov. 20, 2003

(54) Wordline pulldown circuit

(75) Inventor: Paul E. Brucke, Durham, NC (US)

Correspondence Address: BRINKS HOFER GILSON & LIONE, P.O. BOX 10395, CHICAGO, IL, 60611, US

(73) Assignee: Infineon Technologies North America Corp.

(21) Appl. No.: 10/146,395

(22) Filed: May 14, 2002

(51) Int. Cl. G11C 7/00

(52) U.S. Cl. 365/189.11

(57) ABSTRACT

A circuit and method of operation for pulldown of a wordline in a DRAM (dynamic random access memory) are revealed. The circuit adds a transistor at the far end (top) of each wordline (row) in a DRAM, in addition to a transistor already at the near end (bottom) of each row. An inverter driven by a pulse generator drives the transistors at the top of each wordline, bringing them low in about half the time as a present precharge operation requires.

### FIELD OF THE INVENTION

The present invention relates generally to the field of random access memories (RAMs), and more particularly the present invention relates to dynamic random access memories (DRAMs).

### BACKGROUND OF THE INVENTION

Dynamic random access memories (DRAMs) are used extensively in electronic circuits, especially in circuits requiring large amounts of memory in a high speed computing environment. The personal computer is likely the greatest market for these circuits, but other markets also exist, from telecommunications, to Internet and electronic-commerce applications, to graphics and publishing. Whatever the application, users and manufacturers constantly seek to improve both computers and their memories, looking for improvements in everything from software to hardware to better interactions between the two.

One area for improvement is speeding up individual operations in all aspects of reading, writing and refreshing the memory cells of the arrays in a DRAM. Particularly advantageous would be speeding up any operations that are known to be “slow” or bottlenecks in computing capacity. Also advantageous are those changes in which a hardware change is not required, or in which a minimal hardware change is required. Hardware changes are typically changes to the traces of transistors or hard-wired logic circuits in the DRAM or its component parts. Operations that are slower may be those involving a long sequence, such as a column or a row in a DRAM. Many of these sequences now involve 1024, 2048, or even up to 8192 transistors in a row (or column), where any command from the DRAM logic or circuit command is obeyed sequentially.

In order to help speed circuit operation, CMOS technology, typically used for DRAMs, has improved from 0.26 micron to 0.19 micron, and now down to 0.14 micron spacing between traces, with 0.11 micron spacing under development. Closer traces and smaller sizes allow for more memory density in a given area or volume. Closer traces also speed up the processing for memory input and output, as the electrical impulses travel shorter and shorter distances. Of course, each change in trace width, while helpful to memory and computer performance, is also a hardware change, requiring very expensive investment to realize the changes. What is needed is a way to make faster DRAMs. What is needed is a way to speed up the operation of dynamic random access memories (DRAMs), making DRAMs faster than ever before to keep up with the need for ever faster required computing speeds.

### BRIEF SUMMARY

The present embodiments meet this need by providing an apparatus and a method for a faster dynamic random access memory array and for a faster dynamic random access memory. One embodiment of the invention is a memory array having a plurality of wordlines and bitlines, and having a row decoder connected to each wordline and a column decoder connected to each bitline. Each wordline has a wordline driver, and a pulldown circuit connected to the end of each wordline. The array also comprises a pulse generator connected to the pulldown circuits at the end of each wordline, wherein the wordline driver and the pulldown circuit pull down a row of the array upon receiving a signal from the row decoder and the pulse generator.

Another embodiment of the invention is a dynamic random access memory having at least one memory array. Each memory array has a plurality of rows and columns, and a row decoder and a column decoder. The dynamic random access memory also has a control logic and timing generator connected to the at least one memory array. Each memory array also has a pulldown circuit, the pulldown circuit connected to each of the plurality of rows in the array at an end opposite a connection of the row decoder, wherein the row decoder and the pulldown circuit pull down a row of the array upon receiving a signal from the control logic and timing generator.

Another embodiment of the invention is a method of operating a dynamic random access memory. The method comprises providing a memory array having a plurality of wordlines and bitlines, and also having a wordline row decoder connected to a first end of each wordline and having a pulldown circuit connected to a second end of each wordline. The method then includes precharging the array by turning off each wordline, wherein the precharging is accomplished by turning off each row using the row decoder and the pulldown circuit. Another aspect of the invention is another method for pulling down a wordline of a memory array. The method comprises providing a wordline with a row decoder at a first end and a pulldown circuit at a second end of the wordline. The method then applies a low signal through the row decoder and the pulldown circuit upon receiving a signal from control circuitry of the memory array. Many other embodiments and aspects of the invention are also possible.

### BRIEF DESCRIPTION OF SEVERAL VIEWS OF THE DRAWINGS

FIG. 1 is a block diagram of a dynamic random access memory.

FIG. 2 is a detailed view of a wordline in a prior art dynamic random access memory.

FIG. 3 is a view of a wordline incorporating a wordline driver at both ends of a wordline according to the present invention.

FIG. 4 depicts an embodiment of a pulse generator according to the present invention.

FIG. 5 is another view of a wordline and logic circuits according to the present invention.

FIG. 6 depicts signals and timing for wordline pulldown according to the present invention.

FIG. 7 illustrates timing for signals used in the pulldown circuit.

FIG. 8 is a block diagram with another embodiment of a dynamic random access memory having a wordline pulldown circuit.

### DETAILED DESCRIPTION OF THE PRESENTLY PREFERRED EMBODIMENTS

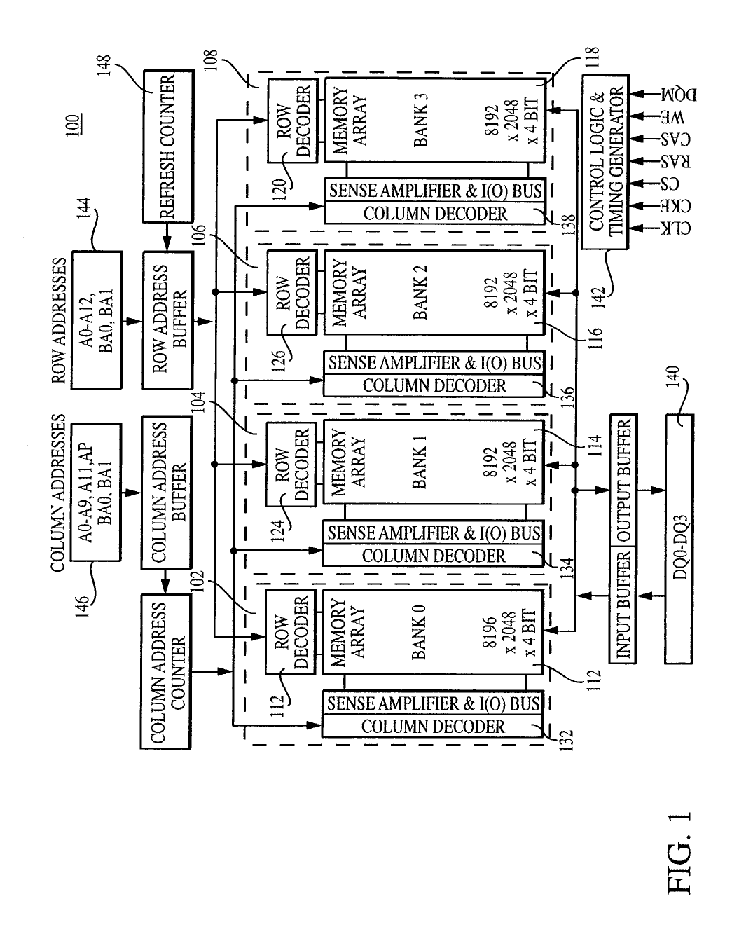

FIG. 1 depicts a CMOS dynamic random access memory (DRAM) 100. This memory is a 64 Megabit×4 synchronous DRAM, having an array of four memory arrays 102, 104, 106 and 108. Each array is capable of storing 8192×2048×4 bits of memory. Each array has a respective memory bank or array 112, 114, 116 and 118, as well as a row decoder 102, 104, 106 and 108, and a column decoder 132, 134, 136, 138. Also included within the DRAM are input/output circuits 140, control logic and timing 142, row address circuitry 144, and column address circuitry 146. There may also be a refresh counter 148 for the constant refreshing necessary for DRAM circuits.

The control circuitry of the DRAM 100 controls the four memory arrays 102, 104, 106 and 108, as well as the memory banks 112, 114, 116, 118, as well as the row decoders and column decoders of the memory banks. In particular, row decoder 122 and column decoder 132 communicate with and control Bank 0 memory array 112, in response to signals from the row and column address circuitry of DRAM 100. In a similar manner, memory array Bank 1 114 receives control signals from row decoder 124 and column decoder 134, and so on for each memory array. Each memory array receives commands from the row decoder and column decoder associated with that memory array, for every operation of involving reading, writing, and refreshing the memory cells of the DRAM.

Row address control circuitry 144 and column address control circuitry 146 control all the operations for reading and writing to each memory bit in DRAM 100. The timing and sequence of operations of each memory array is governed by signals generated from the control logic and timing generator 142. The control logic and timing generator 142 is in communication with the row and column address control circuitry 144, 146 relaying commands to the memory arrays (connecting circuitry not shown for clarity). Commands are ultimately relayed to each memory array and the row and column decoders for each array. For example, the command “precharge,” requires each active wordline to turn off, thus turning off every transistor connected to that wordline. This operation is also known as a wordline “pulldown,” that is, turning off every transistor connected to a wordline in the line of transistors that constitutes a “row”.

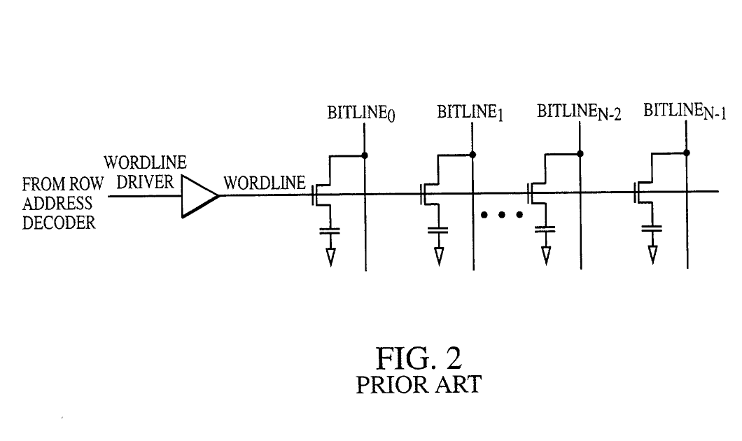

In this embodiment, there are 8192 rows and 2048 columns in each memory array 112, 114, 116, 118 shown in FIG. 1. Therefore, each row has 2048 transistors and each column has 8192 transistors. Thus, in the wordline (row) embodiment depicted in FIG. 2, the numeral N equals 2048, and each row has 2048 transistors, one for each column in the array. FIG. 2 depicts a prior art CMOS wordline having N bits. Each bit consists of a transistor and a capacitor connector to the transistor. The capacitor may store a small charge and be in a “high” state, or the capacitor may be discharged and will be in a “low” state. The capacitor, and thus the bit, may be charged or discharged by turning on the wordline and allowing the bitline for that column (not shown) to charge or discharge the capacitor.

In order to perform an operation on the array, or at least on the wordline depicted in FIG. 2, each transistor must turn on or off. Thus, if the wordline driver receives the command “precharge,” from the row decoder, each transistor will have to turn off. Of course, there is at least a small amount of parasitic resistance and capacitance between each transistor and it will take some time before all of the 2048 transistors in this example will turn off. Put another way, it will take some time to pull the wordline down in preparation for the next command, such as “activate” the wordline. This pulldown sequence may take as long as several nanoseconds, and may contribute to an undesired slowing of the operation of the memory.

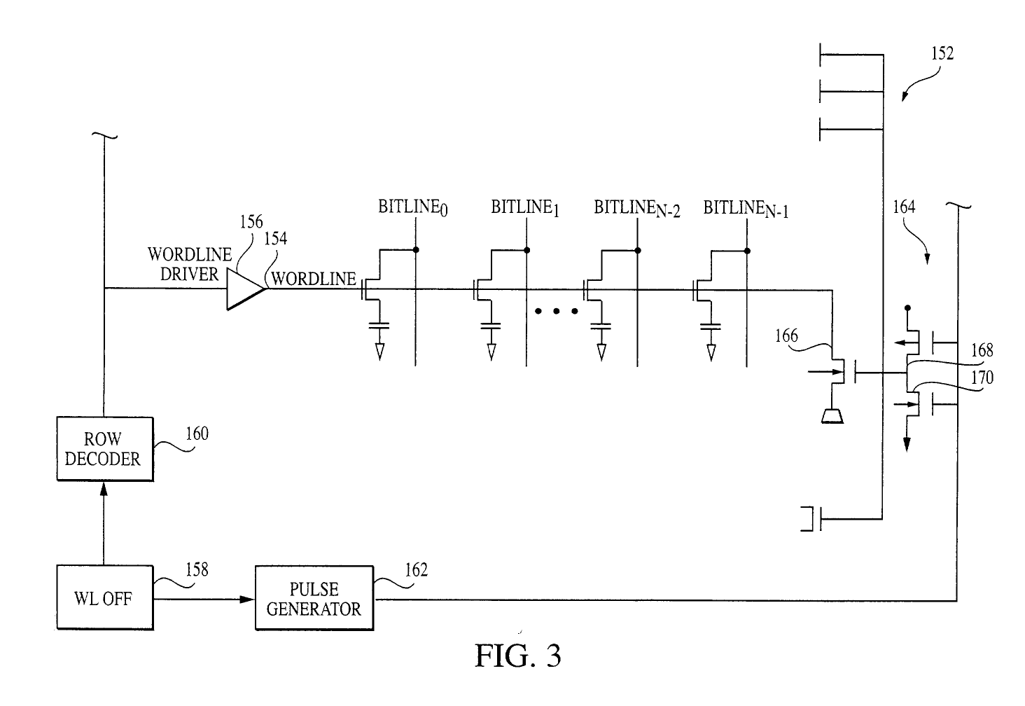

Therefore, an improved DRAM array 152, as shown in FIG. 3, has been devised. One embodiment of the improved DRAM is an improved circuit that changes each wordline (row) 154 in each DRAM array. A row comprises a wordline driver 156 and a line of transistors, as stated above, up to 2048 or even 8192 transistors connected to the wordline driver 156. Each transistor is also connected to a corresponding bitline, that is part of a column line of transistors intersecting with the row. To each DRAM array 152 is now added a pulse generator 162 and at least one transistor to each wordline. In FIG. 3, each wordline is depicted as having a single transistor 166 at the far end (top) of the array. Transistors 166 are driven by pulse generator 162 and redriver transistors 168 and 170. The transistor directly connected to the wordline 154 is an nmos transistor 166, connected in series to a pmos transistor 168 and a second nmos transistor 170.

Operation of the circuit is as follows, to bring each wordline to a low voltage state, rather than a high voltage state. When a signal is given for wordline off from the control circuitry 158, the control circuitry sends signals to row decoder 160 and pulse generator 162, all at the bottom of the array. In this embodiment, that portion of the memory array closest to the wordline driver ends of the wordlines is termed the “bottom” of the array. The opposite end of the array, with the ends of the wordlines that are closest to the pulse generator and the wordline pulldown circuits 164, is termed the “top” of the array. Embodiments in which this convention is reversed may also be used. In one embodiment, the signal for wordline off produces a wordline reset signal to each of the row decoders 160. The row decoders proceed to bring each wordline low, that is, to discharge the wordline from a “high” voltage state to a “low” voltage state. At the same time that the row decoders 160 are being given the signal for wordline reset, the pulse generator is giving the pulldown transistors at the top of the array a signal to reset the wordline. At the same time that the row decoders at the bottom of the array are signaling each gate in a wordline to turn off, the pulse generator is signaling transistors at the top of each array to turn off. The result is that both ends of the wordline now receive the signal to turn off at about the same time, and the signals proceed through the wordline from both the top and the bottom of the array, working toward the middle transistors in the array. The last transistors to be turned off are therefore the transistors in the middle, rather than the transistors at the top of the array. The delay caused by the patristic resistance and capacitance of the wordline is therefore about half of the previous time.

It may be remembered that only a single wordline in an array may be turned on at any one time. Therefore, the procedure described in the above paragraph is used throughout the array, applied to each wordline in the array, even though only a single wordline will have been turned “on” when the signal to turn off is given. One very favorable aspect of the invention is that it is not necessary to know which wordline had been turned on and was active at the time the signal is given to turn off. Rather, the procedure described above may be applied to each memory array by the simple technique of adding the transistors and connecting them to a pulse generator, as shown.

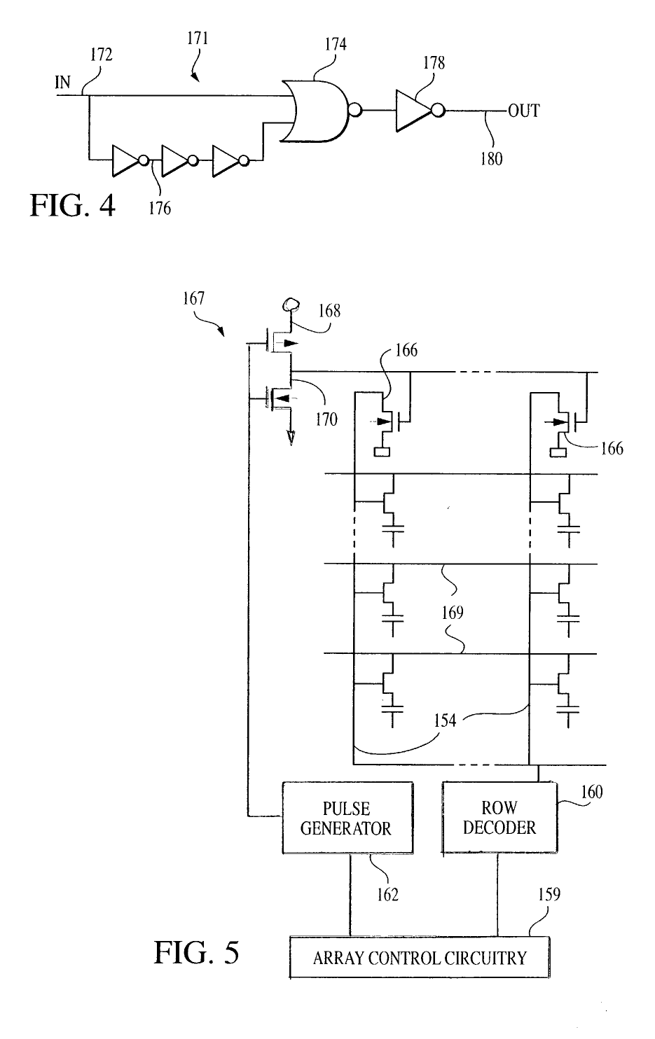

FIG. 4 depicts a pulse generator 171 according to one embodiment of the present invention. The pulse generator may be any circuit that is capable of routing a “turnoff” instruction to the top end of the wordline. In FIG. 4, the pulse generator receives a “wordline off” signal, or other instruction, via input 172. The input is routed to a NOR circuit 174 and to a series of three drivers or inverters 176. The pulse generator creates a “low” pulse that is routed to the top of the array to turn off the wordlines. The input to the pulse generator is given before the command to the row decoder so that there is sufficient time for the signal to reach the top of the array, as the output of the pulse generator will suffer from the same parasitic delay that the wordlines do. Other circuits may also be used. The requirements are merely that the circuit be able give a “wordline off” signal to the top of the array at the same time the “wordline off” command is given to the row decoder. A pulse generator is necessary so that it does not interfere with other operations of the memory circuit, such as wordline rise.

Another embodiment of the memory array circuit 167 uses NMOS transistor 170 and PMOS transistor 168 for redriver transistors and a NMOS transistor 166 on each wordline 154, as depicted in FIG. 5. Array control circuitry 159 includes a row decoder 160 connected to one end of at least one wordline 154 and a pulse generator 162 connected to an opposite end of wordlines 154. Each bit is also part of a column or bitline 169. The row decoder is understood to be in communication with each row in the memory array, at a first end or bottom of the array. The pulse generator is in contact with each row of the array at a second end or top of the array. Array control circuitry 159 sends a “wordline reset” signal to the row decoder 160 and also to the pulse generator 162. The pulse generator sends a “turnoff” pulse to the transistors connected to each wordline at the top of the array, such as the transistor 166, through redriver transistors 168, 170. Thus, the signal to turn off is given by the pulse generator and is transmitted to the top of the memory array and to each wordline in the memory array. As seen from the figures for this embodiment, only a single transistor need be added to each wordline row in the array.

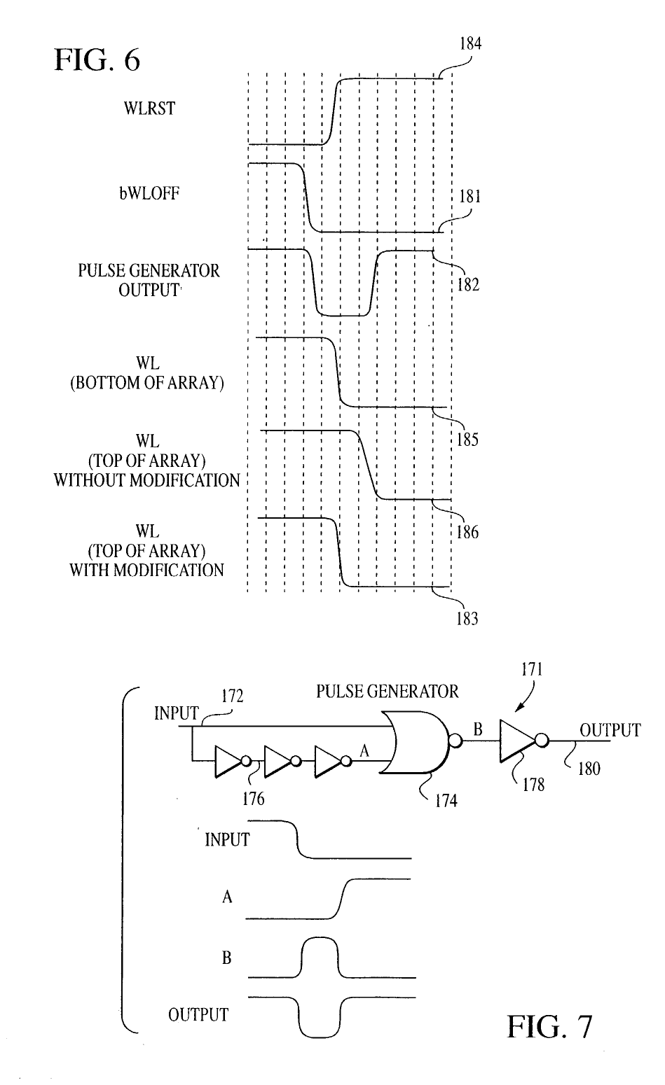

FIG. 6 illustrates the timing sequence of a series of voltage traces, 181-186. The first command given may be to turn off the wordline, shown with voltage trace 181. The command is executed and is sent first to the pulse generator, where it generates a pulse of several nanoseconds duration 182, to the top of the array, where the signal to turn off is given in turn to each wordline. The control circuitry also sends a command, shown by “wordline reset” trace 184 to the row decoder, signaling the wordline to turn off. The result of this operation is seen in that the pulses to turn off are received at about the same time at the top of the array 183 and the bottom of the array 185. By contrast, without the pulse generator and the added transistors at the top of each wordline, there may be a delay of up to several nanoseconds in beginning turnoff at the top of the wordline, as shown by trace 186.

Once the signal has arrived at the top or the wordline, turnoff begins as the signal works its way to each gate of each transistor connected to the wordline. The slowest part of the wordline will thus be in the middle rather than at the top of the wordline.

The timing and output of the pulldown pulses is depicted in FIG. 7. The control circuitry 158 sends out the pulse labeled “input” in FIG. 7. The signal is received at an input 172 to the NOR circuit 174. The same input pulse also is routed to the three inverters in series 176, resulting in a delayed and inverted signal, as shown in the traces labeled “A” and “B”. The NOR gate thus receives a first input and then later a second input. The output signal from the NOR circuit is normally low (trace labeled “output”) and will only go high when both inputs are low. Therefore, the output of the inverted NOR is high for a short period of time and then is pulsed low. Other embodiments of logic circuitry are meant to be included within the claims, so long as they generate a pulse at a far end of a wordline.

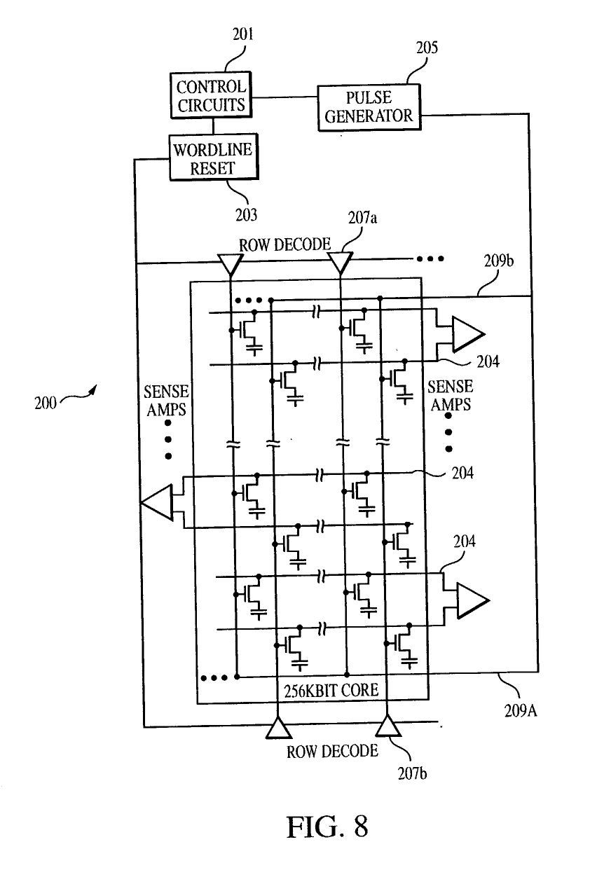

The pulldown circuit is conveniently used in DRAM circuits as shown above. These DRAM circuits may be part of stand-alone memory devices or may be part of memory circuits which are combined with other circuits in a device. The circuit may also be used in designs having slightly less convenient circuits, such as a folded bitline design depicted in FIG. 8. In such designs, the pulldown circuit may become a little more difficult to execute in hardware, but the principle is the same: apply the precharge or wordline low command to an end of each wordline opposite that of the row decoders. In this example, memory array 200 is designed in a folded array format, with the digitlines 204 “folded” at one end and then doubling back to the start point of the digitlines. Each row line intersects a bitline at only one point, and in this embodiment, the wordlines alternate between starting and termination at the top (and at the bottom) of the array. The array is under the control of control and logic circuitry 201. The precharge command may be given to both the wordline reset circuitry 203 and a pulse generator 205 for applying a pulse at opposite ends of the wordlines, the wordline reset command being given to the row decoders 207a, 207b. The precharge command sent to the pulse generator 205 may be processed slightly differently, such as a signal that is faster or slower, before sending to the far ends of the wordlines, depicted as 209a, 209b in FIG. 8.

Although only a few embodiments of the invention have been discussed, other embodiments are contemplated. It is therefore intended that the foregoing description illustrates rather than limits this invention, and that it is the following claims, including all equivalents, which define this invention. Of course, it should be understood that a wide range of changes and modifications may be made to the embodiments described above. Accordingly, it is the intention of the applicants to protect all variations and modifications within the valid scope of the present invention.

What is claimed is:

1. A dynamic random access memory (DRAM) array, comprising:
a memory array having a plurality of wordlines and bitlines;
a row decoder connected to each wordline;
a column decoder connected to each bitline;
a wordline driver and a pulldown circuit connected to each wordline; and
a pulse generator connected to the pulldown circuits at the end of each wordline, wherein the wordline driver and the pulldown circuit pull down a row of the array upon receiving a signal from the row decoder and the pulse generator.

2. The array of claim 1, wherein the pulldown circuit comprises at least one transistor at the end of each row opposite the wordline driver.

3. The array of claim 2 further comprising a pulse generator connected between the control logic and timing generator and the at least one transistor.

4. A dynamic random access memory, comprising:
at least one memory array, each memory array further comprising a column decoder and a row decoder, wherein each row decoder has a wordline driver for each row;
a column address buffer and counter connected to the column decoders;
a row address counter and buffer connected to the row decoders;
a control logic and timing system connected to the at least one memory array, the column decoders and the row decoders; and
a pulldown circuit connected to the control logic and timing generator, said pulldown circuit connected to an end of each row opposite the wordline driver, wherein the wordline driver and the pulldown circuit pull down a row of the array upon receiving a signal from the control logic and timing generator.

5. The dynamic random access memory of claim 4, wherein the pulldown circuit comprises at least one transistor at the end of each row opposite the wordline driver.

6. The dynamic random access memory of claim 5, wherein each array further comprises a pulse generator connected between the control logic and timing generator and the at least one transistor.

7. A dynamic random access memory, comprising:
at least one memory array, each memory array having a plurality of rows and columns, and a row decoder and a column decoder;
a control logic and timing generator connected to the at least one memory array; and
a pulldown circuit in each memory array, the pulldown circuit connected to each row in the array at an end opposite a connection of the row decoder, wherein the row decoder and the pulldown circuit pull down each row of the array upon receiving a signal from the control logic and timing generator.

8. The dynamic random access memory of claim 7, wherein the pulldown circuit comprises a pulse generator and an inverter, connected to each row by at least one transistor.

9. The dynamic random access memory of claim 7, wherein the pulse generator further comprises a NOR circuit.

10. A dynamic random access memory, comprising:
at least one memory array;
control circuitry for the at least one memory array;
a row decoder for each said memory array, said row decoder in communication with a wordline driver at a first end of each wordline in the memory array; and
a pulldown circuit in each said memory array, said pulldown circuit in communication with a second end of each wordline in the memory array, wherein the wordline driver and the pulldown circuit pull down a row of the array upon receiving a signal from the control circuitry.

11. The dynamic random access memory of claim 10 further comprising at least one transistor on each wordline for interfacing with the pulldown circuit.

12. The dynamic random access memory of claim 10 wherein the pulldown circuit further comprises a pulse generator between the control circuitry and the wordlines in each of said memory arrays.

13. A method of operating a dynamic random access memory (DRAM) array, the method comprising:
accessing a memory array having a plurality of wordlines and bitlines, and a wordline row decoder connected to a first end of each wordline and having a pulldown circuit connected to a second end of each wordline;
precharging the array by turning off each row in the wordline, wherein the precharging is accomplished by turning off each row through the row decoder and the pulldown circuit.

14. The method of claim 13 wherein the precharging is accomplished through a wordline off command to the pulldown circuit and a wordline reset command to the row decoder.

15. A method of pulling down a wordline, the method comprising:
accessing a wordline with a row decoder at a first end and a pulldown transistor at a second end of the wordline; and
applying a low signal through the row decoder and the pulldown transistor.

16. The method of claim 15, wherein the low signal is applied through a pulse generator and an inverter connected to the pulldown transistor.

17. A method of operating a dynamic random access memory, the method comprising:
accessing a memory array having a plurality of wordlines and digitlines, and a wordline row decoder connected to a first end of each wordline and having a pulldown circuit connected to a second end of each wordline;
precharging the array by turning off each row in the wordline, wherein the precharging is accomplished by turning off each row through the row decoder and the pulldown circuit.

18. The method of claim 17 wherein the precharging is accomplished through a wordline off command to the pulldown circuit and a wordline reset command to the row decoder.

19. A method of pulling down a wordline, the method comprising:
accessing a wordline with a row decoder at a first end and a pulldown transistor at a second end of the wordline; and
applying a low signal through the row decoder and the pulldown transistor.

20. The method of claim 19, wherein the low signal is applied through a pulse generator and an inverter connected to the pulldown transistor.
